(19) United States
(12) Patent Application Publication
(10) Pub. No.: US 2026/0098339 A1
(43) Pub. Date: Apr. 9, 2026

(54) GAS DIFFUSION ASSEMBLY, GAS INTAKE DEVICE, AND SUBSTRATE PROCESSING DEVICE

(71) Applicant: SwaySure Technology Co. , Ltd., Shenzhen (CN)

(72) Inventor: Takayuki FUKASAWA, Shenzhen (CN)

(21) Appl. No.: 19/308,589

(22) Filed: Aug. 25, 2025

(30) Foreign Application Priority Data
Oct. 9, 2024 (CN) 202411405709.X

(51) Int. Cl. C23C 16/455

(52) U.S. Cl. CPC C23C 16/45559; C23C 16/45561

(57) ABSTRACT

A gas diffusion assembly including a guider. The first end of the guider in the length direction of the guider is used to connect with the gas distributor, and the second end of the guider in the length direction of the guider is used to connect with the reaction chamber. The guider includes a middle flow channel and outer flow channels, two of the outer flow channels respectively provided on opposite sides of the middle flow channel in the width direction of the middle flow channel. Both the outer flow channels and the middle flow channel extend in parallel along the length direction of the guider, and the width ratio of the outer flow channel to the middle flow channel is 40±10:20±20.

### CROSS-REFERENCE TO RELATED APPLICATIONS

This application claims priority to Chinese Patent Application No. 202411405709.X, filed on Oct. 9, 2024, the entire disclosure of which is hereby incorporated herein by reference.

### TECHNICAL FIELD

The present disclosure belongs to the technical field of semiconductor manufacturing device, and specifically relates to a gas diffusion assembly, a gas intake device, and a substrate processing device.

### BACKGROUND

Epitaxial Growth (EPI) is a technology for growing a single-crystal thin film with the same crystal structure and orientation on a single-crystal substrate. During the epitaxial growth process, in order to ensure the uniformity of the film thickness, the gas flow field in the reaction chamber needs to be strictly controlled to make the distribution of the reaction gas above the substrate as uniform as possible.

### SUMMARY

There are provided a gas diffusion assembly, a gas intake device, and a substrate processing device. The technical solution is as below:

According to a first aspect of embodiments of the present disclosure, there is provided a gas diffusion assembly, applied to a gas intake device, the gas intake device further includes a gas distributor, the gas intake device being configured for introducing gas into a reaction chamber;
the gas diffusion assembly comprises a guider, a first end of the guider in a length direction of the guider is configured for connecting with the gas distributor, and a second end of the guider in the length direction of the guider is configured for connecting with the reaction chamber;
the guider includes a middle flow channel and outer flow channels, two of the outer flow channels are respectively provided at two opposite sides of the middle flow channel in a width direction of the middle flow channel;
the outer flow channels and the middle flow channel extend in parallel along the length direction of the guider, and a width ratio of each outer flow channel to the middle flow channel is 40±10:20±20.

According to a second aspect of embodiments of the present disclosure, there is provided a gas intake device, applied for introducing gas into a reaction chamber, including:
a gas distributor, wherein the gas distributor includes a gas inlet end and a gas outlet end, wherein the gas outlet end includes a middle gas outlet and outer gas outlets, two of the outer gas outlets are respectively provided at two opposite sides of the middle gas outlet in a width direction of the middle gas outlet, and the gas inlet end comprises a first pipe interface and a second pipe interface, the first pipe interface is in communication with the middle gas outlet, and the second pipe interface is in communication with the outer gas outlets; and
the gas diffusion assembly, the first end of the guider in the length direction of the guider of the gas diffusion assembly is connected with the gas outlet end, the middle flow channel corresponds to the middle gas outlet, and the outer flow channels correspond to the outer gas outlets.

According to a third aspect of embodiments of the present disclosure, there is provided a substrate processing device, including:
a reaction chamber;
a base provided in the reaction chamber, wherein the base is configured for holding a substrate, and the base is capable of rotating synchronously with the substrate;
the gas intake device, provided at one side of the reaction chamber, wherein the gas intake device is configured for introducing gas along a first direction parallel to the substrate; and
an auxiliary gas intake device, configured for introducing gas along a second direction parallel to the substrate, wherein the second direction is perpendicular to the first direction.

It should be understood that the foregoing general description and the following detailed description are only exemplary and explanatory, and should not limit the present disclosure.

### BRIEF DESCRIPTION OF THE DRAWINGS

The accompanying drawings herein are incorporated into the specification and constitute a part of the specification, illustrating embodiments consistent with the present disclosure, and are used to explain the principles of the present disclosure together with the specification. Obviously, the drawings described below are only some embodiments of the present disclosure, and those skilled in the art can obtain other drawings according to these drawings without creative efforts.

FIG. 1 is a structural schematic diagram of a gas diffusion assembly in an embodiment of the present disclosure.

FIG. 2 is a cross-sectional schematic diagram at the position A-A in FIG. 1.

FIG. 3 is a structural schematic diagram of a substrate processing device in an embodiment of the present disclosure.

FIG. 4(A) is a schematic diagram of reaction gas pressure distribution when reaction gases are uniformly introduced into inner and outer flow channels.

FIG. 4(B) is a schematic diagram of reaction gas pressure distribution when reaction gases are unevenly introduced into inner and outer flow channels.

FIG. 4(C) is a schematic diagram of uniform dispersion of reaction gases in FIG. 4(A) due to wafer rotation.

FIG. 4(D) is a schematic diagram of uniform dispersion of reaction gases in FIG. 4(B) due to wafer rotation.

FIG. 4(E) is a schematic diagram of total gas distribution on the wafer in FIG. 4(C).

FIG. 4(F) is a schematic diagram of total gas distribution on the wafer in FIG. 4(D).

FIG. 5(A) is a schematic diagram of reaction gas pressure distribution in an existing reaction chamber with less intermediate gas intake.

FIG. 5(B) is a schematic diagram of reaction gas pressure distribution in an existing reaction chamber with more intermediate gas intake.

FIG. 6(A) is a schematic diagram of reaction gas pressure distribution when middle gas intake is less in an embodiment of the present disclosure.

FIG. 6(B) is a schematic diagram of reaction gas pressure distribution when middle gas intake is more in an embodiment of the present disclosure.

FIG. 7 is an exploded schematic diagram of a guider in an embodiment of the present disclosure.

FIG. 8 is a structural schematic diagram of a gas distributor in an embodiment of the present disclosure.

### DETAILED DESCRIPTION OF THE EMBODIMENTS

Now, example embodiments will be described more fully with reference to the accompanying drawings. However, the example embodiments can be implemented in various forms and should not be construed as limited to the examples set forth herein; rather, these embodiments are provided so that this application will be thorough and complete, and will fully convey the concept of the example embodiments to those skilled in the art.

Furthermore, the described features, structures, or characteristics may be combined in any suitable manner in one or more embodiments. In the following description, numerous specific details are provided to give a sufficient understanding of the embodiments of the present disclosure. However, those skilled in the art will recognize that the technical solutions of the present disclosure may be practiced without one or more of the specific details, or other methods, components, devices, steps, etc. may be employed. In other instances, well-known methods, devices, implementations, or operations are not shown or described in detail to avoid obscuring aspects of the present disclosure.

The present disclosure will be further described in detail below with reference to the accompanying drawings and specific embodiments. It should be noted here that the technical features involved in the various embodiments of the present disclosure described below can be combined with each other as long as they do not conflict with each other. The embodiments described below with reference to the drawings are exemplary and are intended to explain the present disclosure and should not be construed as limiting the present disclosure.

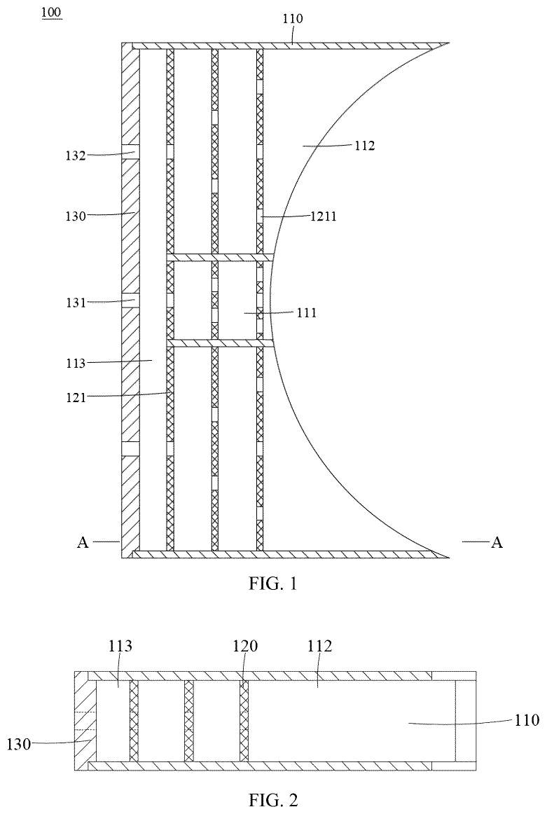

Referring to FIGS. 1 to 3, in this embodiment, a gas diffusion assembly 100 is applied to a gas intake device 10, and the gas intake device 10 is used to introduce gas into a reaction chamber 20. The gas diffusion assembly 100 includes a guider 110. The gas intake device 10 further includes a gas distributor 200. A first end of the guider 110 in the length direction is used to connect to the gas distributor 200, and a second end of the guider 110 in the length direction is used to connect to the reaction chamber 20.

The guider 110 includes a middle flow channel 111 and outer flow channels 112. Two outer flow channels 112 are respectively provided on opposite sides of the middle flow channel 111 in the width direction. Both the outer flow channels 112 and the middle flow channel 111 extend in parallel along the length direction. The width ratio of the outer flow channel 112 to the middle flow channel 111 is 40±10:20±20, that is, the middle flow channel 111 is a narrow flow channel relative to the outer flow channels 112. In the height direction, the outer flow channels 112 and the middle flow channel 111 may have the same height and be at the same height position.

In the related art, the width ratio of the outer flow channel to the middle flow channel is about 20:60, and the width of the outer flow channel of the guider is smaller than the width of the middle flow channel. The middle flow channel is used to introduce gas with a uniformly distributed flow rate into the reaction chamber, and the outer flow channels are used to introduce gas to adjust the gas flow rate at the edge of the reaction chamber. The gas flow rates in the middle flow channel and the outer flow channels can be independently adjusted.

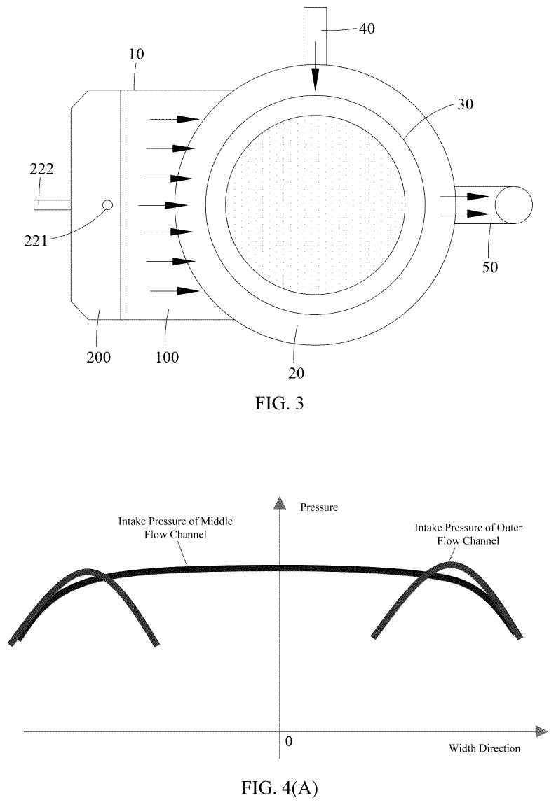

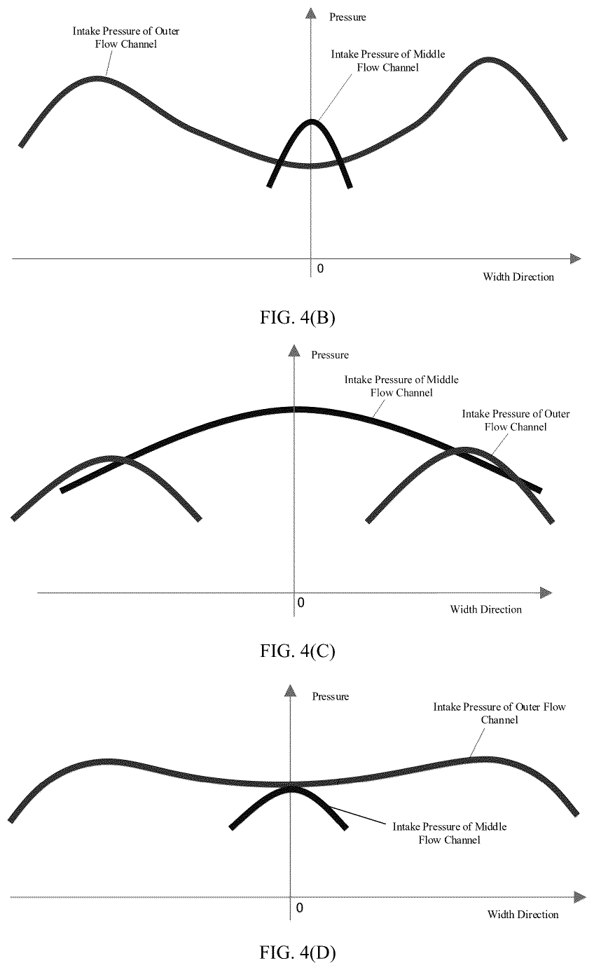

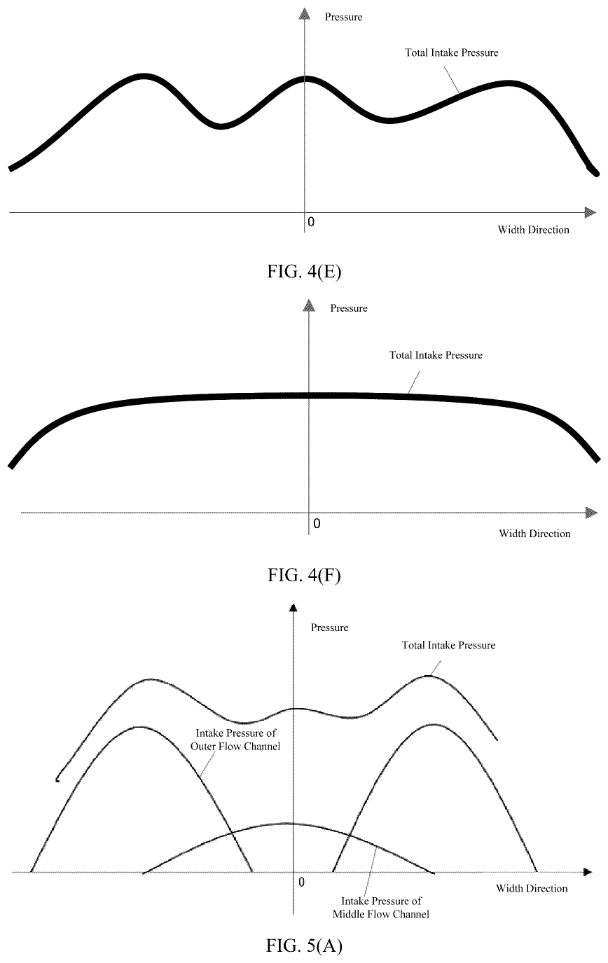

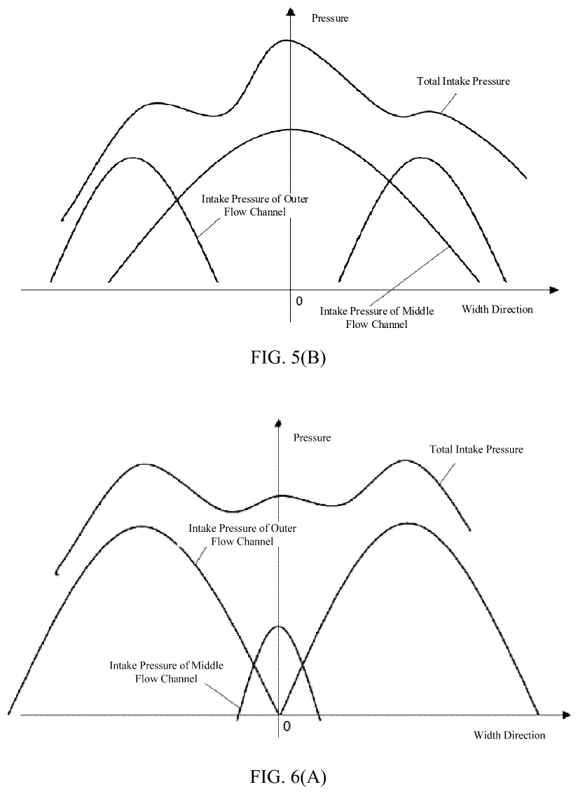

When the existing substrate processing device processes the substrate, the reaction gas introduced into the reaction chamber through the middle flow channel is initially uniformly distributed, as shown in FIG. 4(A). It is difficult to provide uniformly distributed reaction gas, and under the action of wafer rotation, the uniformity of the originally uniformly introduced reaction gas decreases, as shown in FIG. 4(C), resulting in non-uniform total gas distribution on the wafer, as shown in FIG. 4(E). Finally, the film layer deposited on the wafer is non-uniform. Further, as shown in FIG. 5(A) to 5(B), in order to achieve uniform gas distribution, when increasing the intake flow rate of the middle flow channel, since the middle gas flow and the outer gas flows are very close, the gases quickly mix with each other after entering the reaction chamber. The middle gas flow is widely distributed and has a large influence, resulting in an increase in the gas pressure in the two side regions of the substrate, such that the reaction gas distribution in the reaction chamber is still non-uniform. That is, although the reaction gas introduced into the reaction chamber is initially uniform, whether increasing or decreasing the intake pressure of the middle flow channel cannot make the reaction gas distribution in the reaction chamber uniform.

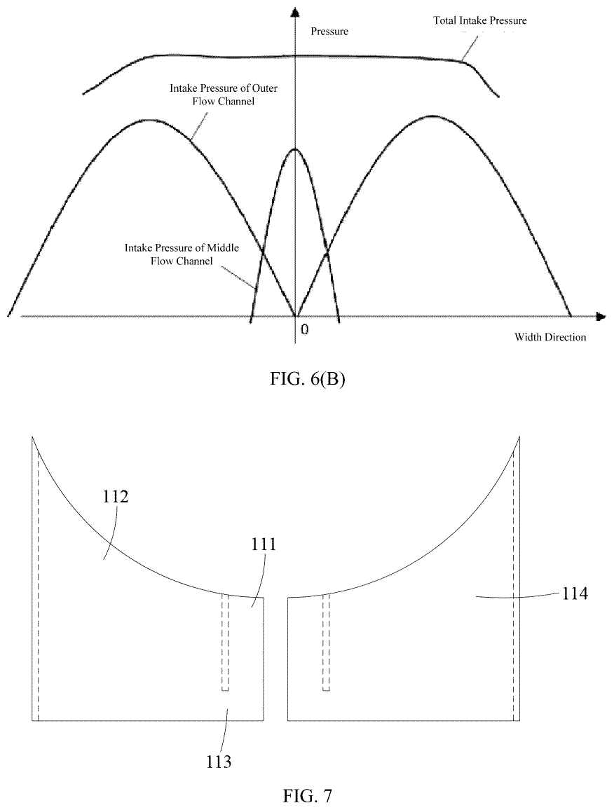

When the substrate processing device in this embodiment processes the substrate, the reaction gas introduced through the outer flow channels 112 and the reaction gas introduced through the middle flow channel 111 may not be uniform, as shown in FIG. 4(B). As the wafer rotates, the total distribution of the two outer gas flows and the distribution of the middle gas flow both tend to become uniform, as shown in FIG. 4(D). Further, as shown in FIG. 6(A) to 6(B), in order to achieve uniform gas distribution, when increasing the intake flow rate of the middle flow channel, since the middle gas flow is narrowly distributed, its adjustment has little influence on the change of the gas pressure in the two side regions of the substrate. Thus, by adjustment of the narrow middle gas flow and wafer rotation, uniform gas distribution on the wafer can be achieved without providing uniformly distributed gas (FIG. 4(F)), and the difficulty of gas introduction is reduced.

For example, if in the width direction of the guider 110, the gas pressure in the central region of the substrate is lower than the gas pressure in the two side regions of the substrate, that is, the reaction gas distribution in the reaction chamber 20 is non-uniform, as shown in FIG. 6(A), the uniformity of the deposited or epitaxially grown film layer is reduced. As shown in FIG. 6(B), by increasing the intake pressure of the middle flow channel 111, the gas pressure in the central region of the substrate can be increased. The width ratio of the outer flow channel 112 to the middle flow channel 111 is 40±10:20±20, and the middle flow channel 111 is a narrow flow channel. The reaction gas introduced through the middle flow channel 111 will only increase the gas pressure in the central region of the substrate and has little influence on the gas pressure in the two side regions of the substrate, so that the reaction gas distribution in the reaction chamber 20 can be made uniform. That is, by increasing or decreasing the intake pressure of the middle flow channel 111, the reaction gas distribution in the reaction chamber 20 can be made uniform.

Further, when the substrate processing device in this embodiment processes the substrate, the gas initially introduced into the reaction chamber is non-uniform. Thus, an auxiliary gas flow can be added to improve the uniformity of the gas distribution at the wafer edge. In one example, the intake direction of the auxiliary gas flow is perpendicular to the intake directions of the outer flow channels 112 and the middle flow channel 111.

In this embodiment, the gas diffusion assembly 100 includes a guider 110. A first end of the guider 110 in the length direction is used to connect to the gas distributor 200, and a second end of the guider 110 in the length direction is used to connect to the reaction chamber 20. The guider 110 includes a middle flow channel 111 and outer flow channels 112. Two outer flow channels 112 are respectively provided on opposite sides of the middle flow channel 111 in the width direction. Both the outer flow channels 112 and the middle flow channel 111 extend in parallel along the length direction. The width ratio of the outer flow channel 112 to the middle flow channel 111 is 40±10:20±20. Since the middle flow channel 111 is a narrow flow channel relative to the outer flow channels 112, by increasing or decreasing the intake pressure of the middle flow channel 111, the gas pressure in the central region of the substrate can be increased or decreased without affecting the gas pressure in the two side regions of the substrate, so that the reaction gas distribution in the reaction chamber 20 is made uniform, and the thickness uniformity of the deposited or epitaxially grown film layer is improved.

In some embodiments, the width of the outer flow channel 112 is greater than the width of the middle flow channel 111.

The width of the outer flow channel 112 is greater than the width of the middle flow channel 111, which can prevent increasing or decreasing the intake pressure of the middle flow channel 111 from affecting the gas pressure in the two side regions of the substrate, resulting in non-uniform reaction gas distribution in the reaction chamber 20.

In some embodiments, the width ratio of the outer flow channel 112 to the middle flow channel 111 is 40±5:20±10. For example, the width ratio of the outer flow channel 112 to the middle flow channel 111 is 40:20.

When the width of the outer flow channel 112 is twice or more than twice the width of the middle flow channel 111, increasing or decreasing the intake pressure of the middle flow channel 111 has little influence on the gas pressure in the two side regions of the substrate, so that the reaction gas distribution in the reaction chamber 20 can be made uniform.

Referring to FIGS. 1 and 2, the gas diffusion assembly 100 further includes a diffusion plate component 120. The diffusion plate component 120 is provided in at least one of the outer flow channel 112 and the middle flow channel 111. Preferably, the diffusion plate component 120 can be provided in each outer flow channel 112 and the middle flow channel 111. The diffusion plate component 120 includes n diffusion plates 121 spaced apart along the length direction of the guider 110, where n is greater than or equal to 2. For example, the diffusion plate component 120 includes three diffusion plates 121 spaced apart along the length direction of the guider 110.

The diffusion plates 121 are provided with first holes 1211. From the first end of the guider 110 to the second end of the guider 110 in the length direction, that is, in the gas flow direction, the number of the first holes 1211 in the diffusion plates 121 increases and the diameters of the first holes 1211 decrease.

The diffusion plate component 120 includes a plurality of diffusion plates 121 spaced apart along the length direction of the guider 110, and in the gas flow direction, the number of the first holes 1211 in each diffusion plate 121 increases and the diameters of the first holes 1211 decrease. This design can uniformly disperse the gas flow, and the diffusion plates 121 are spaced apart, so that the gas can be mixed in the space between the diffusion plates 121, further improving the uniformity of the reaction gas distribution introduced into the reaction chamber 20.

In some embodiments, when a plurality of first holes 1211 are provided in the diffusion plate 121, the plurality of first holes 1211 are uniformly spaced apart along the width direction.

Since the number of the first holes 1211 in the diffusion plate 121 increases and the diameters the first holes 1211 decrease, from the first end of the guider 110 to the second end of the guider 110 in the length direction, at least two first holes 1211 are provided in the second diffusion plate 121, and at least three first holes 1211 are provided in the third diffusion plate 121. The plurality of first holes 1211 are uniformly spaced apart along the width direction, which is beneficial to further uniformly disperse the gas flow and improve the uniformity of the reaction gas distribution in the reaction chamber 20.

In some embodiments, the diffusion plate component 120 includes three diffusion plates 121 spaced apart along the length direction of the guider 110. From the first end of the guider 110 to the second end of the guider 110 in the length direction, one first hole 1211 is provided in the first diffusion plate 121, and the first hole 1211 can be provided at the center, that is, located at the middle position in the width direction of the middle flow channel 111 or the outer flow channel 112 where it is located, and located at the middle position in the height direction of the middle flow channel 111 or the outer flow channel 112 where it is located. The diameter of the first hole 1211 in the first diffusion plate 121 is 4±0.5 mm, for example, 3.5 mm, 4 mm, 4.5 mm, etc.

The second diffusion plate 121 is provided with two first holes 1211. In the height direction, two first holes 1211 are centrally provided in the middle flow channel 111 or the outer flow channel 112 where they are located. In the width direction, the two first holes 1211 are symmetrical about the middle cross-section of the middle flow channel 111 or the outer flow channel 112 where they are located. The diameters of the first holes 1211 in the second diffusion plate 121 are 2 mm to 2.8 mm. In the middle flow channel 111, the spacing between the two first holes 1211 is 10±1 mm, for example, 9 mm, 10 mm, 11 mm, etc. In the outer flow channel 112, the spacing between the two first holes 1211 is 20±1 mm, for example, 19 mm, 20 mm, 21 mm, etc.

The third diffusion plate 121 is provided with three first holes 1211. In the height direction, the three first holes 1211 are centrally provided in the middle flow channel 111 or the outer flow channel 112 where they are located. In the width direction, the three first holes 1211 are symmetrical about the middle cross-section of the middle flow channel 111 or the outer flow channel 112 where they are located, that is, the centrally located first hole 1211 passes through the middle cross-section, and the other two first holes 1211 are located on both sides of the middle cross-section. The diameters of the first holes 1211 in the third diffusion plate 121 are 1.5 mm to 2.3 mm. In the middle flow channel 111, the spacing between the two first holes 1211 is 10±1 mm, for example, 9 mm, 10 mm, 11 mm, etc. In the outer flow channel 112, the spacing between the two first holes 1211 is 20±1 mm, for example, 19 mm, 20 mm, 21 mm, etc.

Along the gas flow direction, the number of the first holes 1211 in the diffusion plates 121 increases and the diameters of the first holes 1211 decrease, and an appropriate hole spacing is set according to the width of the flow channel, so that the gas is gradually dispersed, which is beneficial to further uniformly disperse the gas flow and improve the uniformity of the reaction gas distribution in the reaction chamber 20.

It should be noted that the arrangement manner of the first holes 1211 in the middle flow channel 111 and the arrangement manner of the first holes 1211 in the outer flow channel 112 may be different. For example, the number, size, or position of the first holes 1211 in the middle flow channel 111 and that of the first holes 1211 in the outer flow channel 112 are different. In the width direction, the distance between the middle cross-section of the outer flow channel 112 and the middle cross-section of the middle flow channel 111 is about 11 cm. The first holes 1211 in the outer flow channel 112 may also be symmetrical about a plane 11 cm away from the middle cross-section of the middle flow channel 111.

In the above embodiments, the first holes 1211 in the diffusion plate 121 are provided in one row in the height direction, but it is not limited thereto. In some embodiments, the first holes 1211 in the diffusion plate 121 may be provided in multiple rows, which may be specifically determined according to the situation.

In addition, the diffusion plate 121 may be fixedly connected to the guider 110, but it is not limited thereto. The diffusion plate 121 may also be detachably connected to the guider 110, which may be specifically determined according to the situation. When the diffusion plate 121 is detachably connected to the guider 110, the spacing between adjacent diffusion plates 121 and the number, size, and position of the first holes 1211 in the diffusion plate 121 can all be adjusted.

Referring to FIGS. 1 to 3, a mixing zone 113 is provided at the first end of the guider 110. The mixing zone 113 is used to connect to the gas distributor 200. Both the outer flow channel 112 and the middle flow channel 111 are connected to the mixing zone 113.

The mixing zone 113 is provided at the first end of the guider 110. The reaction gas from the gas distributor 200 is first mixed in the mixing zone 113 and then introduced into the reaction chamber 20 through the outer flow channel 112 and the middle flow channel 111 respectively, which can make the mixing of the two paths of reaction gas introduced by the gas distributor 200 more uniform.

Referring to FIGS. 1 to 3, the gas diffusion assembly 100 further includes a flow equalizing plate 130. The flow equalizing plate 130 is provided between the guider 110 and the gas distributor 200. The flow equalizing plate 130 includes outer parts corresponding to the outer flow channels 112 and a middle part corresponding to the middle flow channel 111. The middle part includes at least one second hole 131, and the outer part includes at least one third hole 132. The distance between the second hole 131 and the third hole 132 is greater than 3 cm.

The flow equalizing plate 130 is provided between the guider 110 and the gas distributor 200. The reaction gas from the gas distributor 200 is first uniformly dispersed through the flow equalizing plate 130 and then enters the mixing zone 113 for mixing, which can make the mixing of the two paths of reaction gas introduced by the gas distributor 200 more uniform.

For example, one second hole 131 or one third hole 132 is correspondingly provided for each flow channel, that is, the middle part includes one second hole 131, and each outer part includes one third hole 132. The diameters of the second hole 131 and the third hole 132 are 4±0.5 mm, for example, 3.5 mm, 4 mm, 4.5 mm, etc. The second hole 131 may be centrally provided relative to the middle flow channel 111, and the third hole 132 may be centrally provided relative to the outer flow channel 112.

In some embodiments, two second holes 131 or third holes 132 are correspondingly provided for each flow channel, that is, the middle part includes two second holes 131, and the outer part includes two third holes 132. The diameter of the second hole 131 and the third hole 132 is 4±0.5 mm, for example, 3.5 mm, 4 mm, 4.5 mm, etc. In the height direction, the two second holes 131 may be centrally provided relative to the middle flow channel 111, and the two third holes 132 may be centrally provided relative to the outer flow channel 112. In the width direction, the two second holes 131 may be symmetrically provided relative to the middle cross-section of the middle flow channel 111, and the two third holes 132 may be symmetrically provided relative to the middle cross-section of the outer flow channel 112.

In some embodiments, three or more second holes 131 or third holes 132 are correspondingly provided for each flow channel, that is, the middle part includes three or more second holes 131, and the outer part includes three or more third holes 132. The diameter of the second hole 131 and the diameter of the third hole 132 are 2 mm to 3 mm. In the height direction, the plurality of second holes 131 may be centrally provided relative to the middle flow channel 111, and the plurality of third holes 132 may be centrally provided relative to the outer flow channel 112. In the width direction, the plurality of second holes 131 are provided at equal intervals, and the plurality of second holes 131 are symmetrically provided relative to the middle cross-section of the middle flow channel 111. The plurality of third holes 132 are provided at equal intervals, and the plurality of third holes 132 are symmetrically provided relative to the middle cross-section of the outer flow channel 112.

In some embodiments, three or more second holes 131 or third holes 132 are correspondingly provided for each flow channel, that is, the middle part includes three or more second holes 131, and the outer part includes three or more third holes 132. The diameter of the second hole 131 and that of the third hole 132 are 1 mm to 3 mm, and from the inside to the outside, the diameter of the holes gradually decreases or increases. In the height direction, the plurality of second holes 131 may be centrally provided relative to the middle flow channel 111, and the plurality of third holes 132 may be centrally provided relative to the outer flow channel 112. In the width direction, the plurality of second holes 131 are provided at equal intervals, and the plurality of second holes 131 are symmetrically provided relative to the middle cross-section of the middle flow channel 111. The plurality of third holes 132 are provided at equal intervals, and the plurality of third holes 132 are symmetrically provided relative to the middle cross-section of the outer flow channel 112.

It should be noted that the arrangement manner of the second holes 131 and the arrangement manner of the third holes 132 may be different. For example, the number, size, or position of the second holes 131 and that of the third holes 132 are different. In the width direction, the distance between the middle cross-section of the outer flow channel 112 and the middle cross-section of the middle flow channel 111 is about 11 cm. The third holes 132 of the outer flow channel 112 may also be symmetrical about a plane 11 cm away from the middle cross-section of the middle flow channel 111.

In the above embodiments, the second holes 131 and the third holes 132 are provided in one row in the height direction, but it is not limited thereto. In some embodiments, the second holes 131 and the third holes 132 may be provided in multiple rows, which may be specifically determined according to the situation.

Referring to FIG. 1, the second end of the guider 110 may have an arc-shaped groove to fit the reaction chamber 20 which is a rotating body. The guider 110 may be designed as an integral body, but it is not limited thereto. The guider 110 may also be split into two guide segments 114 along the central cross-section in the width direction, as shown in FIG. 7, which may be specifically determined according to the situation.

The guider 110 is split into two guide segments 114, which can reduce the structural complexity of the guider 110 and facilitate manufacturing.

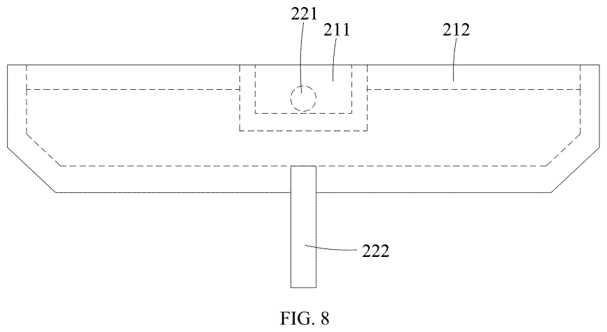

The present disclosure further provides a gas intake device 10 for introducing gas into the reaction chamber 20. Referring to FIGS. 1, 2, 3, and 8, the gas intake device 10 includes the gas diffusion assembly 100 and the gas distributor 200 disclosed above. The gas distributor 200 includes a gas inlet end and a gas outlet end. The gas outlet end includes a middle gas outlet 211 and outer gas outlets 212. The two outer gas outlets 212 are respectively provided on opposite sides of the middle gas outlet 211 in the width direction. The gas inlet end includes a first pipe interface 221 and a second pipe interface 222. The first pipe interface 221 is in communication with the middle gas outlet 211, and the second pipe interface 222 is in communication with the outer gas outlets 212. The height of the outer gas outlet 212 is equal to the height of the middle gas outlet 211, and the width ratio of the outer gas outlet 212 to the middle gas outlet 211 may be approximately equal to the width ratio of the outer flow channel 112 to the middle flow channel 111.

The first end of the guider 110 of the gas diffusion assembly 100 in the length direction of the guider 110 is connected to the gas outlet end of the gas distributor 200. The middle flow channel 111 corresponds to the middle gas outlet 211, and the outer flow channels 112 correspond to the outer gas outlets 212. When the gas diffusion assembly 100 further includes the flow equalizing plate 130, the flow equalizing plate 130 may be provided between the guider 110 and the gas distributor 200. When the gas intake device 10 is in operation, the first path of reaction gas is introduced into the reaction chamber 20 through the first pipe interface 221, the middle gas outlet 211, the second hole 131, and the middle flow channel 111. The second path of reaction gas is introduced into the reaction chamber 20 through the second pipe interface 222, the outer gas outlet 212, the third hole 132, and the outer flow channel 112.

In this embodiment, the gas intake device 10 includes the gas diffusion assembly 100, and the gas diffusion assembly 100 includes the guider 110. The first end of the guider 110 in the length direction is used to connect with the gas distributor 200, the second end of the guider 110 in the length direction is used to connect with the reaction chamber 20. The guider 110 includes the middle flow channel 111 and the outer flow channels 112. Two outer flow channels 112 are respectively provided on opposite sides of the middle flow channel 111 in the width direction. Both the outer flow channels 112 and the middle flow channel 111 extend in parallel along the length direction, and the width ratio of the outer flow channel 112 to the middle flow channel 111 is 40±10:20±20. Since the middle flow channel 111 is a narrow flow channel relative to the outer flow channels 112, by increasing or decreasing the intake pressure of the middle flow channel 111, the gas pressure in the central region of the substrate can be increased or decreased without affecting the gas pressure in the two side regions of the substrate, so that the reaction gas distribution in the reaction chamber 20 is uniform, and the thickness uniformity of the deposited or epitaxially grown film layer is improved.

The present disclosure also provides a substrate processing device. As shown in FIG. 3, the substrate processing device includes the above-disclosed gas intake device 10, a reaction chamber 20, a base 30, an auxiliary gas intake device 40, and an exhaust device 50. The base 30 is provided in the reaction chamber 20, the base 30 is configured for holding a substrate, and the base 30 can rotate synchronously with the substrate. The gas intake device 10 is provided on one side of the reaction chamber 20 in the first direction, the gas intake device 10 is configured for introducing gas along the first direction parallel to the substrate, the exhaust device 50 is provided on the other side of the reaction chamber 20 in the first direction, and the exhaust device 50 is configured for discharging residual reaction gas. The auxiliary gas intake device 40 is configured for introducing auxiliary gas flow along the second direction parallel to the substrate, and the second direction is perpendicular to the first direction.

The substrate processing device processes the substrate including depositing or epitaxially growing a film layer on the substrate. When the substrate processing device works, the reaction gas is introduced into the reaction chamber 20 through the gas intake device 10. Since the width of the middle flow channel 111 is small, by increasing or decreasing the intake pressure of the middle flow channel 111, the gas pressure in the central region of the substrate can be increased or decreased without affecting the gas pressure in the two side regions of the substrate, so that the reaction gas distribution in the reaction chamber 20 is uniform. At the same time, the auxiliary gas flow is introduced along the second direction parallel to the substrate through the auxiliary gas intake device 40, which can increase the thickness of the film layer formed in the edge region of the substrate, and finally achieve the purpose of uniform overall thickness of the formed film layer.

Terms such as “first” and “second” are only used for descriptive purposes and cannot be understood as indicating or implying relative importance or implicitly specifying the number of indicated technical features. Thus, features defined with “first”, “second”, etc. may explicitly or implicitly include one or more of such features. In the description of the present disclosure, “a plurality of” means two or more, unless otherwise specifically defined.

In the present disclosure, unless otherwise clearly specified and limited, terms such as “assemble” and “connect” should be understood in a broad sense. For example, they may be fixedly connected, detachably connected, or integrated; they may be mechanically connected or electrically connected; they may be directly connected, or indirectly connected through an intermediate medium, or the internal communication of two components or the interaction relationship between two components. For those skilled in the art, the specific meanings of the above terms in the present disclosure can be understood according to specific situations.

In the description of this specification, the description referring to terms such as “some embodiments” and “exemplarily” means that specific features, structures, materials, or characteristics described in conjunction with the embodiment or example are included in at least one embodiment or example of the present disclosure. In this specification, the schematic representations of the above terms do not necessarily refer to the same embodiment or example. Moreover, the described specific features, structures, materials, or characteristics may be combined in any suitable manner in any one or more embodiments or examples. In addition, those skilled in the art can combine and combine the different embodiments or examples and the features of the different embodiments or examples described in this specification without conflicting with each other.

Although the embodiments of the present disclosure have been shown and described above, it can be understood that the above embodiments are exemplary and should not be construed as limiting the present disclosure. Those skilled in the art can make changes, modifications, substitutions, and variations to the above embodiments within the scope of the present disclosure. Therefore, any changes or modifications made according to the claims and the specification of the present disclosure shall fall within the scope covered by the patent of the present disclosure.

What is claimed is:

1. A gas diffusion assembly, applied to a gas intake device comprising a gas distributor, the gas intake device being configured for introducing gas into a reaction chamber;
wherein the gas diffusion assembly comprises a guider, a first end of the guider in a length direction of the guider is configured for connecting with the gas distributor, and a second end of the guider in the length direction of the guider is configured for connecting with the reaction chamber;
the guider comprises a middle flow channel and a plurality of outer flow channels, two of the plurality of outer flow channels are respectively provided at two opposite sides of the middle flow channel in a width direction of the middle flow channel; and
the plurality of outer flow channels and the middle flow channel extend in parallel along the length direction of the guider, and a width ratio of each outer flow channel to the middle flow channel is 40±10:20±20.

2. The gas diffusion assembly according to claim 1, wherein a width of each outer flow channel is greater than a width of the middle flow channel.

3. The gas diffusion assembly according to claim 2, wherein the width ratio of each outer flow channel to the middle flow channel is 40±5:20±10.

4. The gas diffusion assembly according to claim 2, wherein the width of each outer flow channel is twice or more than twice the width of the middle flow channel.

5. The gas diffusion assembly according to claim 1, further comprising a diffusion plate component, wherein the diffusion plate component is provided in at least one channel from a group consisting of the plurality of outer flow channels and the middle flow channel.

6. The gas diffusion assembly according to claim 5, wherein the diffusion plate component is provided in each outer flow channel and the middle flow channel.

7. The gas diffusion assembly according to claim 5, wherein the diffusion plate component comprises at least two diffusion plates provided at intervals along the length direction of the guider, each diffusion plate is provided with at least one first hole.

8. The gas diffusion assembly according to claim 7, wherein a number of first holes in each diffusion plate increases from the first end of the guider to the second end of the guider in the length direction of the guider.

9. The gas diffusion assembly according to claim 7, wherein diameters of first holes decrease from the first end of the guider to the second end of the guider in the length direction of the guider.

10. The gas diffusion assembly according to claim 7, wherein when a plurality of first holes are provided in each diffusion plate, the plurality of first holes are uniformly spaced along the width direction of the guider.

11. The gas diffusion assembly according to claim 7, wherein in the width direction of the guider, a spacing between adjacent first holes in the middle flow channel is 10±1 mm.

12. The gas diffusion assembly according to claim 7, wherein in the width direction of the guider, a spacing between adjacent first holes in each outer flow channel is 20±1 mm.

13. The gas diffusion assembly according to claim 7, wherein a diameter of each first hole is 1.5 mm to 4 mm.

14. The gas diffusion assembly according to claim 7, wherein first holes in each diffusion plate are provided in multiple rows in a height direction.

15. The gas diffusion assembly according to claim 7, wherein each diffusion plate is detachably connected to the guider.

16. The gas diffusion assembly according to claim 1, wherein the guider is split into two guide segments along a central cross-section in the width direction of the guider.

17. The gas diffusion assembly according to claim 1, wherein a mixing zone is provided at the first end of the guider, the mixing zone is configured for connecting with the gas distributor, and the plurality of outer flow channels and the middle flow channel are connected with the mixing zone.

18. The gas diffusion assembly according to claim 1, further comprising a flow equalizing plate, wherein the flow equalizing plate is provided between the guider and the gas distributor, the flow equalizing plate comprises outer parts corresponding to the plurality of outer flow channels and a middle part corresponding to the middle flow channel; and
the middle part comprises at least one second hole, and each outer part comprises at least one third hole, and a distance between each second hole and each third hole is greater than 3 cm.

19. A gas intake device, applied for introducing gas into a reaction chamber, comprising:
a gas distributor, comprising a gas inlet end and a gas outlet end, wherein the gas outlet end comprises a middle gas outlet and a plurality of outer gas outlets, two of the plurality of outer gas outlets are respectively provided at two opposite sides of the middle gas outlet in a width direction of the middle gas outlet, the gas inlet end comprises a first pipe interface and a second pipe interface, the first pipe interface is in communication with the middle gas outlet, and the second pipe interface is in communication with the plurality of outer gas outlets; and
a gas diffusion assembly comprising a guider;
wherein a first end of the guider in a length direction of the guider is configured for connecting with the gas outlet end, and a second end of the guider in the length direction of the guider is configured for connecting with the reaction chamber; the guider comprises a middle flow channel corresponding to the middle gas outlet and a plurality of outer flow channels corresponding to the plurality of outer gas outlets, and two of the plurality of outer flow channels are respectively provided at two opposite sides of the middle flow channel in a width direction of the middle flow channel; and the plurality of outer flow channels and the middle flow channel extend in parallel along the length direction of the guider, and a width ratio of each outer flow channel to the middle flow channel is 40±10:20±20.

20. A substrate processing device, comprising:
a reaction chamber;
a base, provided in the reaction chamber, wherein the base is configured for holding a substrate, and the base is capable of rotating synchronously with the substrate;
a gas intake device, provided at one side of the reaction chamber, configured for introducing gas into the reaction chamber along a first direction parallel to the substrate; and
an auxiliary gas intake device, configured for introducing gas along a second direction parallel to the substrate, wherein the second direction is perpendicular to the first direction;
wherein the gas intake device comprises:
a gas distributor, comprising a gas inlet end and a gas outlet end, wherein the gas outlet end comprises a middle gas outlet and a plurality of outer gas outlets, two of the plurality of outer gas outlets are respectively provided at two opposite sides of the middle gas outlet in a width direction of the middle gas outlet, the gas inlet end comprises a first pipe interface and a second pipe interface, the first pipe interface is in communication with the middle gas outlet, and the second pipe interface is in communication with the plurality of outer gas outlets; and
a gas diffusion assembly comprising a guider;
wherein a first end of the guider in a length direction of the guider is configured for connecting with the gas outlet end, and a second end of the guider in the length direction of the guider is configured for connecting with the reaction chamber; the guider comprises a middle flow channel corresponding to the middle gas outlet and a plurality of outer flow channels corresponding to the plurality of outer gas outlets, and two of the plurality of outer flow channels are respectively provided at two opposite sides of the middle flow channel in a width direction of the middle flow channel; and the plurality of outer flow channels and the middle flow channel extend in parallel along the length direction of the guider, and a width ratio of each outer flow channel to the middle flow channel is 40±10:20±20.
